(19) United States
(12) Patent Application Publication
(10) Pub. No.: US 2017/0077241 A1
(43) Pub. Date: Mar. 16, 2017

(54) SEMICONDUCTOR DEVICE

(71) Applicant: Kabushiki Kaisha Toshiba, Tokyo (JP)

(72) Inventors: Akira Yoshioka, Kanazawa Ishikawa (JP); Hung Hung, Nonoichi Ishikawa (JP); Yasuhiro Isobe, Kanazawa Ishikawa (JP)

(21) Appl. No.: 15/062,754

(22) Filed: Mar. 7, 2016

(30) Foreign Application Priority Data
Sep. 10, 2015 (JP) 2015-178386

(51) Int. Cl. H01L 29/20; H01L 29/205; H01L 29/778

(52) U.S. Cl. CPC H01L 29/2003; H01L 29/7787; H01L 29/205

(57) ABSTRACT

According to embodiments, a semiconductor device includes a first laminated nitride semiconductor layer in which first nitride semiconductor layers and second nitride semiconductor layers are alternately laminated; a third nitride semiconductor layer; a fourth nitride semiconductor layer; a drain electrode; a source electrode; and a gate electrode. The first nitride semiconductor layer is carbon-containing gallium nitride. The second nitride semiconductor layer contains aluminum indium nitride. The third nitride semiconductor layer is on the first laminated nitride semiconductor layer and includes gallium nitride. The fourth nitride semiconductor layer is on the third nitride semiconductor layer and contains aluminum gallium nitride. The drain electrode and the source electrode are on the fourth nitride semiconductor layer. The gate electrode is between the drain electrode and the source electrode.

### CROSS-REFERENCE TO RELATED APPLICATIONS

This application is based upon and claims the benefit of priority from Japanese Patent Application No. 2015-178386, filed on Sep. 10, 2015; the entire contents of which are incorporated herein by reference.

### FIELD

The embodiments of the present invention relate to a semiconductor device.

### BACKGROUND

A field-effect transistor with nitride semiconductor layers is known as one example of semiconductor devices. This field-effect transistor comprises, for example, a substrate, a buffer layer, a carbon-doped gallium nitride (GaN) layer, an un-doped gallium nitride layer and an un-doped aluminum gallium nitride (AlGaN) layer. A current pathway (channel) called as a two-dimensional electron gas is formed in the interfacial boundary between the un-doped gallium nitride layer and the un-doped aluminum gallium nitride layer.

When the field-effect transistor is driven, the substrate and a source electrode may be grounded and a positive voltage may be applied to a drain electrode. In this case, electrons are injected from the substrate and holes are injected from the drain electrode due to an electric field generated between the substrate and the drain electrode. Electrons and holes are liable to be trapped in the carbon-doped gallium nitride layer. If the number of trapped electrons is greater than the number of trapped holes at this time, this gallium nitride layer becomes negatively charged. In this case, the density of the abovementioned two-dimensional electron gas decreases due to maintain charge neutrality within the crystal. As a result, a so-called current collapse phenomenon in which ON-resistance increases occurs.

A method for not forming the carbon-doped gallium nitride layer is conceivable as a method for preventing the occurrence of the above-described current collapse phenomenon. Since this method results in the absence of a semiconductor layer high in specific resistance, however, there is a concern over a decrease in voltage resistance.

The embodiments of the present invention provide a semiconductor device capable of preventing an increase in ON-resistance while ensuring voltage resistance.

### BRIEF DESCRIPTION OF THE DRAWINGS

FIG. 1 is a cross-sectional view illustrating the schematic structure of a semiconductor device according to a first embodiment;

FIG. 2 is a drawing schematically illustrating a band structure along an A-A line shown in FIG. 1;

FIG. 3 is a cross-sectional view illustrating the schematic structure of a semiconductor device according to a second embodiment; and

FIG. 4 is a drawing schematically illustrating a band structure along a B-B line shown in FIG. 1.

### DETAILED DESCRIPTION

Embodiments will now be explained with reference to the accompanying drawings. The present invention is not limited to the embodiments.

### First Embodiment

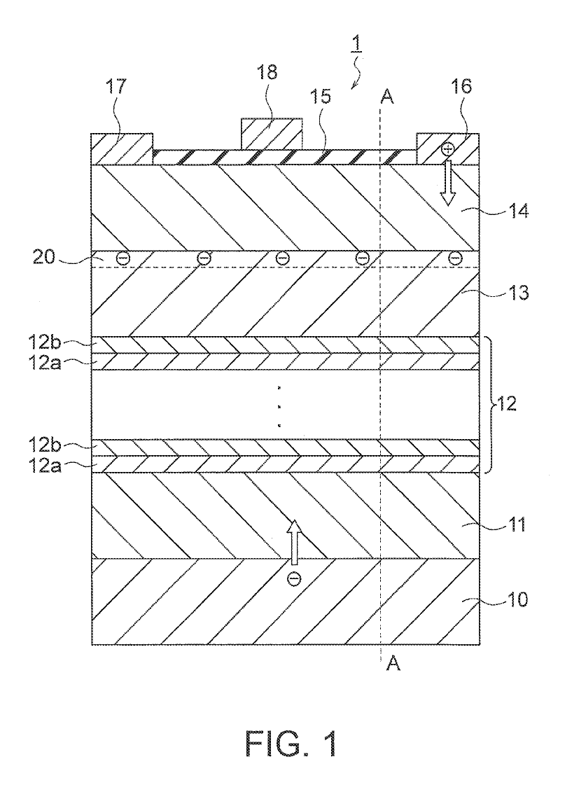

FIG. 1 is a cross-sectional view illustrating the schematic structure of a semiconductor device according to the present embodiment. As illustrated in FIG. 1, a semiconductor device 1 according to the present embodiment comprises a substrate 10; a buffer layer 11; a first laminated nitride semiconductor layer 12 in which first nitride semiconductor layers 12a and second nitride semiconductor layers 12b are alternately laminated; a third nitride semiconductor layer 13; a fourth nitride semiconductor layer 14; an insulating film 15; a drain electrode 16; a source electrode 17; and a gate electrode 18.

The substrate 10 is a silicon substrate or the like. The buffer layer 11 is on the substrate 10.

The buffer layer 11 according to the present embodiment constitutes a first buffer layer. This buffer layer 11 contains aluminum nitride (AlN) or the like. By the buffer layer 11, any mismatch in lattice constant between the substrate 10 and the first laminated nitride semiconductor layer 12 is relieved. The first laminated nitride semiconductor layer 12 is on the buffer layer 11.

The first laminated nitride semiconductor layer 12 has a superlattice (SL) structure in which the first nitride semiconductor layers 12a of carbon-doped gallium nitride and the second nitride semiconductor layers 12b of aluminum indium nitride (InAlN) are alternately laminated a plurality of times. The third nitride semiconductor layer 13 is on the first laminated nitride semiconductor layer 12.

The first nitride semiconductor layers 12a and the second nitride semiconductor layers 12b are alternately formed by epitaxially growing the layers using, for example, an MOCVD (Metal Organic Chemical Vapor Deposition) method. At this time, the thickness of each second nitride semiconductor layer 12b is designed as appropriate, by taking into consideration a critical film thickness and the like with which each second nitride semiconductor layer 12b can be retained as a crystal for each first nitride semiconductor layer 12a serving as a base of epitaxial crystal. In the present embodiment, the thickness of each first nitride semiconductor layer 12a is approximately 20 nm, whereas the thickness of each second nitride semiconductor layer 12b is approximately 5 nm. In addition, the content ratio of indium in each second nitride semiconductor layer 12b is approximately 75%.

The third nitride semiconductor layer 13 contains un-doped gallium nitride. The fourth nitride semiconductor layer 14 is on the third nitride semiconductor layer 13. The third nitride semiconductor layer 13 is also formed by epitaxially growing the layer using, for example, an MOCVD method. In the present embodiment, the thickness of the third nitride semiconductor layer 13 is approximately 1 μm.

Here, an un-doped layer is a layer formed without voluntary impurity implantation and does not mean a layer in which the impurity has been diffused and mixed from an upper layer and a lower layer after forming the un-doped layer and/or by the thermal processing. In other words, an impurity density of the un-doped layer is approximately less than 1×10¹⁷/cm³.

The fourth nitride semiconductor layer 14 contains un-doped aluminum gallium nitride, a bandgap of the fourth nitride semiconductor layer 14 being larger than that of the third nitride semiconductor layer 13. The insulating film 15, the drain electrode 16 and the source electrode 17 are on the fourth nitride semiconductor layer 14.

The fourth nitride semiconductor layer 14 is also formed by epitaxially growing the layer using an MOCVD method. In the present embodiment, the thickness of the fourth nitride semiconductor layer 14 is approximately 20 nm. In addition, the content ratio of aluminum in the fourth nitride semiconductor layer 14 is approximately 12%.

The insulating film 15 contains, for example, silicon nitride (SiN) or oxide silicon (SiO₂). The gate electrode 18 is on the insulating film 15. The insulating film 15 is formed using, for example, a CVD (Chemical Vapor Deposition) method.

The gate electrode 18 is a film using, for example, a vacuum deposition or by sputtering. Thereafter, the electrode is formed by processing the film into a desired shape using a liftoff method or by etching. The drain electrode 16 and the source electrode 17 are on the fourth nitride semiconductor layer 14, so as to face each other with the gate electrode 18 sandwiched therebetween.

In the semiconductor device 1 configured as described above, a heterostructure is formed by the third nitride semiconductor layer 13 and the fourth nitride semiconductor layer 14. This heterostructure causes a high-mobility two-dimensional electron gas 20 to be generated in the interfacial boundary between the third nitride semiconductor layer 13 and the fourth nitride semiconductor layer 14. This two-dimensional electron gas 20 forms a current pathway (channel) between the drain electrode 16 and the source electrode 17. A current flowing through this current pathway is controlled by adjusting the voltage of the gate electrode 18. That is, the semiconductor device 1 is driven as a high electron mobility transistor (HEMT).

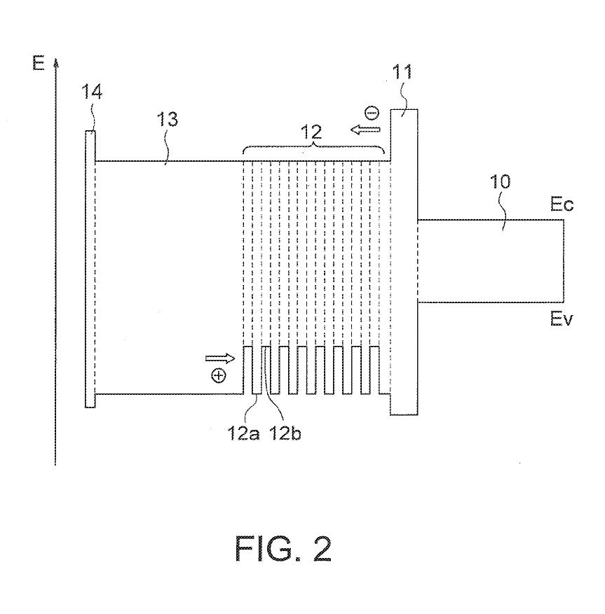

Hereinafter, the band structure of the semiconductor device 1 according to the present embodiment will be described with reference to FIG. 2, FIG. 2 is a drawing schematically illustrating a band structure along an A-A line shown in FIG. 1.

As described above, each first nitride semiconductor layer 12a contains carbon-doped gallium nitride and each second nitride semiconductor layer 12b contains aluminum indium nitride. Accordingly, the valence band (Ev) of each first nitride semiconductor layer 12a and the valence band of each second nitride semiconductor layer 12b are discontinuous to each other in the first laminated nitride semiconductor layer 12, as illustrated in FIG. 2. On the other hand, the conduction band (Ec) of each first nitride semiconductor layer 12a and the conduction band of each second nitride semiconductor layer 12b are continuous to each other.

When the semiconductor device 1 is driven as the abovementioned high electron mobility transistor, the substrate 10 and the source electrode 17 may be grounded and a positive voltage may be applied to the drain electrode 16. In this case, electrons are injected from the substrate 10 and holes are injected from the drain electrode 16.

Assume at this time that the first laminated nitride semiconductor layer 12 includes the first nitride semiconductor layers 12a but does not include the second nitride semiconductor layers 12b. Then, a multitude of electrons are trapped in the first nitride semiconductor layers 12a, and therefore, the first laminated nitride semiconductor layer 12 may become negatively charged, though voltage resistance is ensured. Consequently, ON-resistance may increase due to a current collapse phenomenon.

However, in the first laminated nitride semiconductor layer 12 according to the present embodiment, the conduction band of each first nitride semiconductor layer 12a and the conduction band of each second nitride semiconductor layer 12b are continuous to each other. In other words, the difference in valence band between each first nitride semiconductor layer 12a and each second nitride semiconductor layer 12b is equal to or smaller than 0.2 eV. Consequently, electrons having entered the first laminated nitride semiconductor layer 12 from the substrate 10 are easily discharged smoothly out of the first laminated nitride semiconductor layer 12.

In addition, the valence band of each first nitride semiconductor layer 12a and the valence band of each second nitride semiconductor layer 12b are discontinuous to each other. In other words, each first nitride semiconductor layer 12a and each second nitride semiconductor layer 12b differ in valence band. Consequently, holes injected from the drain electrode 16 have difficulty in entering the first laminated nitride semiconductor layer 12. In addition, holes discharged from the carbon-doped first nitride semiconductor layers 12a are easily trapped in the first laminated nitride semiconductor layer 12.

According to the semiconductor device 1 of the present embodiment described above, the first laminated nitride semiconductor layer 12 is easy to discharge electrons and to trap holes. Consequently, the first laminated nitride semiconductor layer 12 easily becomes positively charged, and therefore, the density of the two-dimensional electron gas 20 is less likely to become lower. Accordingly, a current collapse phenomenon is less likely to occur, thus making it possible to prevent an increase in ON-resistance.

Note that a bias in hole distribution within the first laminated nitride semiconductor layer 12 becomes greater with an increase in the film thickness of the second nitride semiconductor layers 12b, thus reducing the effect of trapping holes. Accordingly, the maximum allowable film thickness of the second nitride semiconductor layers 12b is preferably set on the basis of the abovementioned effect. In addition, the minimum number of lamination of the first nitride semiconductor layers 12a and the second nitride semiconductor layers 12b is preferably set on the basis of this maximum allowable film thickness. For example, the number of lamination of the first nitride semiconductor layers 12a and the second nitride semiconductor layers 12b is preferably at least 80.

In addition, the difference in conduction band between each first nitride semiconductor layer 12a and each second nitride semiconductor layer 12b is equal to or smaller than approximately 0.2 eV, in order for electrons having entered the first laminated nitride semiconductor layer 12 from the substrate 10 to be smoothly discharged. In order to realize this difference, each second nitride semiconductor layer 12b preferably contains aluminum indium nitride that satisfies, for example, the relationship InₓAl₁₋ₓN (0.6<x<0.9). More preferably, each second nitride semiconductor layer 12b contains aluminum indium nitride whose content ratio of indium is 75% (x=0.75). The reason for this is that in this case, the difference in conduction band between each first nitride semiconductor layers 12a and each second nitride semiconductor layers 12b is equal to or smaller than 0.01 eV, and therefore, the two conduction bands are almost the same.

### Second Embodiment

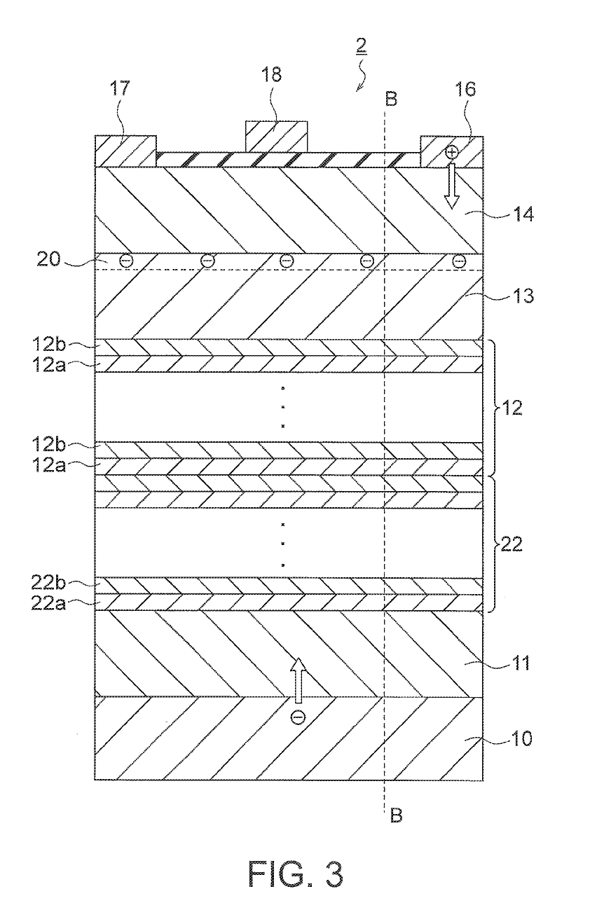

A second embodiment will be described with a focus on differences from the first embodiment. FIG. 3 is a cross-sectional view illustrating the schematic structure of a semiconductor device according to the second embodiment. Hereinafter, constituent parts the same as those of the above-described first embodiment are denoted by the same reference numerals and characters and will not be described in detail here.

As illustrated in FIG. 3, a semiconductor device 2 according to the present embodiment differs from the semiconductor device 1 according to the first embodiment in that the semiconductor device 2 is further comprises a second laminated nitride semiconductor layer 22. The second laminated nitride semiconductor layer 22 is between the buffer layer 11 and the first laminated nitride semiconductor layer 12. Note that the buffer layer 11 according to the present embodiment constitutes a second buffer layer, and the structure of the buffer layer is the same as that in the first embodiment.

The second laminated nitride semiconductor layer 22 has a superlattice structure in which fifth nitride semiconductor layers 22a of carbon-doped gallium nitride and sixth nitride semiconductor layers 22b of aluminum nitride are alternately laminated a plurality of times.

The fifth nitride semiconductor layers 22a and the sixth nitride semiconductor layers 22b are alternately formed by epitaxially growing the layers using an MOCVD method, as in the case of the first laminated nitride semiconductor layer 12. At this time, the thickness of each sixth nitride semiconductor layer 22b is designed as appropriate, by taking into consideration a critical film thickness and the like with which each sixth nitride semiconductor layer 22b can be retained as a crystal for each fifth nitride semiconductor layer 22a serving mainly as a base of epitaxial crystal. In the present embodiment, the thickness of each fifth nitride semiconductor layer 22a is approximately 20 nm, and the thickness of each sixth nitride semiconductor layer 22b is approximately 5 nm.

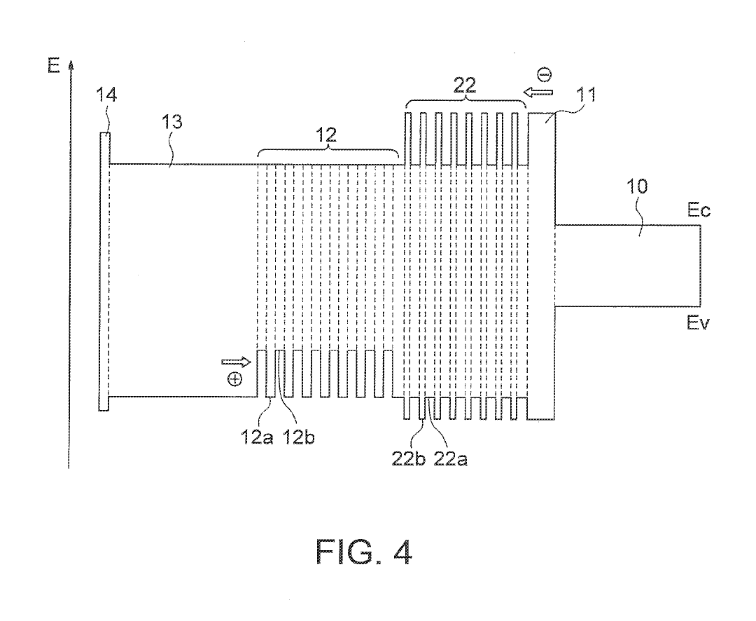

Hereinafter, the band structure of the semiconductor device 2 according to the present embodiment will be described with reference to FIG. 4. FIG. 4 is a drawing schematically illustrating a band structure along a BB line shown in FIG. 3.

As described above, each fifth nitride semiconductor layer 22a contains carbon-doped gallium nitride and each sixth nitride semiconductor layer 22b contains aluminum nitride. Accordingly, the valence band of each fifth nitride semiconductor layer 22a and the valence band of each sixth nitride semiconductor layer 22b are discontinuous to each other in the second laminated nitride semiconductor layer 22, as illustrated in FIG. 4. In other words, each fifth nitride semiconductor layer 22a differs in valence band from each sixth nitride semiconductor layer 22b. In the present embodiment, the difference in valence band between each fifth nitride semiconductor layer 22a and each sixth nitride semiconductor layer 22b is approximately 0.8 eV.

In addition, the conduction band of each fifth nitride semiconductor layer 22a and the conduction band of each sixth nitride semiconductor layer 22b are also discontinuous to each other. In other words, each fifth nitride semiconductor layer 22a also differs in conduction band from each sixth nitride semiconductor layer 22b. In the present embodiment, the difference in conduction band between each fifth nitride semiconductor layer 22a and each sixth nitride semiconductor layer 22b is approximately 1.9 eV.

According to the semiconductor device 2 of the present embodiment described above, the valence band of each first nitride semiconductor layer 12a and the valence band of each second nitride semiconductor layer 12b are discontinuous to each other, whereas the conduction band of each first nitride semiconductor layer 12a and the conduction band of each second nitride semiconductor layer 12b are continuous to each other, as in the semiconductor device 1 according to the first embodiment. That is, the semiconductor device 2 has a structure in which the first laminated nitride semiconductor layer 12 easily becomes positively charged. Consequently, the density of the two-dimensional electron gas 20 is less likely to become lower. Accordingly, a current collapse phenomenon is less likely to occur, thus making it possible to prevent an increase in ON-resistance.

In addition, the semiconductor device 2 of the present embodiment comprises the second laminated nitride semiconductor layer 22 between the first laminated nitride semiconductor layer 12 and the buffer layer 11. In the second laminated nitride semiconductor layer 22, the conduction band of each fifth nitride semiconductor layer 22a and the conduction band of each sixth nitride semiconductor layer 22b are discontinuous to each other. Accordingly, electrons injected from the substrate 10, which may be able to pass through the buffer layer 11, have difficulty in entering the second laminated nitride semiconductor layer 22. Electron injection into the first laminated nitride semiconductor layer 12 disposed on the second laminated nitride semiconductor layer 22 is therefore disturbed, causing the first laminated nitride semiconductor layer 12 to more easily become positively charged. Consequently, it is possible to further prevent an increase in ON-resistance due to a current collapse phenomenon.

Yet additionally, since the valence band of each fifth nitride semiconductor layer 22a and the valence band of each sixth nitride semiconductor layer 22b are also discontinuous to each other in the second laminated nitride semiconductor layer 22, holes discharged from the carbon-doped fifth nitride semiconductor layer 22a can be easily trapped in the second laminated nitride semiconductor layer 22. Accordingly, the second laminated nitride semiconductor layer 22 also easily becomes positively charged. It is therefore possible to prevent the occurrence of a current collapse phenomenon even if the second laminated nitride semiconductor layer 22 is formed.

Note that a bias in hole distribution within the second laminated nitride semiconductor layer 22 becomes greater with an increase in the film thickness of the fifth nitride semiconductor layers 22a, thus reducing the effect of trapping holes. Accordingly, the maximum allowable film thickness of the fifth nitride semiconductor layers 22a is preferably set on the basis of the abovementioned effect. In addition, the minimum number of lamination of the fifth nitride semiconductor layers 22a and the sixth nitride semiconductor layers 22b is preferably set on the basis of this maximum allowable film thickness. For example, the number of lamination of the fifth nitride semiconductor layers 22a and the sixth nitride semiconductor layers 22b is preferably at least 40.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first laminated nitride semiconductor layer in which first nitride semiconductor layers of carbon-containing gallium nitride and second nitride semiconductor layers of aluminum indium nitride are alternately laminated;
a third nitride semiconductor layer on the first laminated nitride semiconductor layer and of gallium nitride;
a fourth nitride semiconductor layer on the third nitride semiconductor layer and of aluminum gallium nitride;
a drain electrode and a source electrode on the fourth nitride semiconductor layer; and
a gate electrode between the drain electrode and the source electrode.

2. The semiconductor device according to claim 1, further comprising a first buffer layer under the first laminated nitride semiconductor layer and of aluminum nitride,

3. The semiconductor device according to claim 1, further comprising a second laminated nitride semiconductor layer which is under the first laminated nitride semiconductor layer and in which fifth nitride semiconductor layers of carbon-containing gallium nitride and sixth nitride semiconductor layers of aluminum nitride are alternately laminated.

4. The semiconductor device according to claim 3, further comprising a second buffer layer under the second laminated nitride semiconductor layer and of aluminum nitride.

5. The semiconductor device according to claim 1, wherein the composition formula of aluminum indium nitride of the second nitride semiconductor layers is InₓAl₁₋ₓN (0.6<x<0.9).

6. The semiconductor device according to claim 3, wherein the composition formula of aluminum indium nitride of the second nitride semiconductor layers is InₓAl₁₋ₓN (0.6<x<0.9).

7. The semiconductor device according to claim 1, wherein the number of lamination of the first nitride semiconductor layers and the second nitride semiconductor layers is at least 80.

8. The semiconductor device according to claim 3, wherein the number of lamination of the fifth nitride semiconductor layers and the sixth nitride semiconductor layers is at least 40.

9. A semiconductor device comprising:
a first laminated nitride semiconductor layer in which first nitride semiconductor layers and second nitride semiconductor layers are alternately laminated, wherein a valence band of the first nitride semiconductor layers differs from a valence band of the second nitride semiconductor layers, and a difference between a conduction band of the first nitride semiconductor layer and a conduction band of the second nitride semiconductor layer is equal to or smaller than 0.2 eV;
a third nitride semiconductor layer on the first laminated nitride semiconductor layer;
a fourth nitride semiconductor layer on the third nitride semiconductor layer, a bandgap of the fourth nitride semiconductor layer being larger than that of the third nitride semiconductor layer;
a drain electrode and a source electrode on the fourth nitride semiconductor layer; and
a gate electrode between the drain electrode and the source electrode.

10. The semiconductor device according to claim 9, further comprising a second laminated nitride semiconductor layer in which fifth nitride semiconductor layers and sixth nitride semiconductor layers are alternately laminated, wherein a valence band of the fifth nitride semiconductor layers differs from a valence band of the sixth nitride semiconductor layers, and a conduction band of the fifth nitride semiconductor layers also differs from a conduction band of the sixth nitride semiconductor layers.

11. The semiconductor device according to claim 9, wherein the number of lamination of the first nitride semiconductor layers and the second nitride semiconductor layers is at least 80.

12. The semiconductor device according to claim 10, wherein the number of lamination of the fifth nitride semiconductor layers and the sixth nitride semiconductor layers is at least 40.
